(19) United States
(12) Patent Application Publication
(10) Pub. No.: US 2008/0122966 A1
(43) Pub. Date: May 29, 2008

(54) CAMERA MODULE

(75) Inventors: Chen Feng, Snohomish, WA (US); Ming Lee, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/681,723

(22) Filed: Mar. 2, 2007

(30) Foreign Application Priority Data
Nov. 24, 2006 (CN) 200610157034.7

(51) Int. Cl. H04N 5/225; H01L 27/00

(52) U.S. Cl. 348/340; 348/374; 250/208.1

(57) ABSTRACT

A camera module (100) includes an image sensor (10), a lens module (14), and an aperture plate (16). The image senor includes a base (102) and a sensor area/region (104) located in the center of the base. The lens module (14) incorporates a plurality of lenses (140) and a container (142) for holding the lenses, the lenses being distributed in an array within the container. The aperture plate has a plurality of light permeable portions located at positions corresponding to the respective lenses. The lens module and the aperture plate correspond to the sensor area of the image sensor. The area of the container corresponds to the area of the aperture plate.

### BACKGROUND OF THE INVENTION

1. Field of the Invention

The present invention generally relates to camera modules and, especially, to a camera module with a low profile.

2. Description of Related Art

Nowadays, digital camera modules are in widespread use in a variety of portable electronic devices. For example, digital camera modules are now widely available as a special feature for mobile phones, and since the mobile phones have become smaller and smaller, the digital camera modules used in the mobile phones are also becoming correspondingly reduced in size.

To achieve ultra small cameras or “card cameras”, various efforts have be made to improve such camera technology, but, due to technical difficulties and performance limitations, the development of the ultra small camera is still suffering problems.

Accordingly, what is needed is a low profile camera module.

### SUMMARY

In one aspect thereof, a camera module includes an image sensor, a lens module, an aperture plate, and a signal processor. The image senor includes a base and a sensor area located in the center of the base. The lens module includes a plurality of lenses and a container configured (i.e., structured and arranged) for containing/carrying the lenses, and the lenses are distributed in an array within the container. The aperture plate includes a plurality of light permeable portions located at positions corresponding to the respective lenses. The signal processor is electronically connected with the image sensor and is configured for processing the signals from the image sensor. The lens module and the aperture plate, respectively, corresponded to the sensor area. The area of the container corresponds to the area of the aperture plate.

Other advantages and novel features will become more apparent from the following detailed description when taken in conjunction with the accompanying drawings.

### BRIEF DESCRIPTION OF THE DRAWINGS

Many aspects of the present camera module can be better understood with reference to the following drawings. The components in the drawings are not necessarily drawn to scale, the emphasis instead being placed upon clearly illustrating the principles of the present camera module. Moreover, in the drawings, like reference numerals designate corresponding parts throughout the several views.

FIG. 1 is an assembled, isometric view of a camera module, in accordance with a preferred embodiment;

FIG. 2 is an exploded, isometric view of the camera module in FIG. 1; and

FIG. 3 is a cross-sectional view of a spacer, taken along line III-III within FIG. 2.

### DETAILED DESCRIPTION OF THE INVENTION

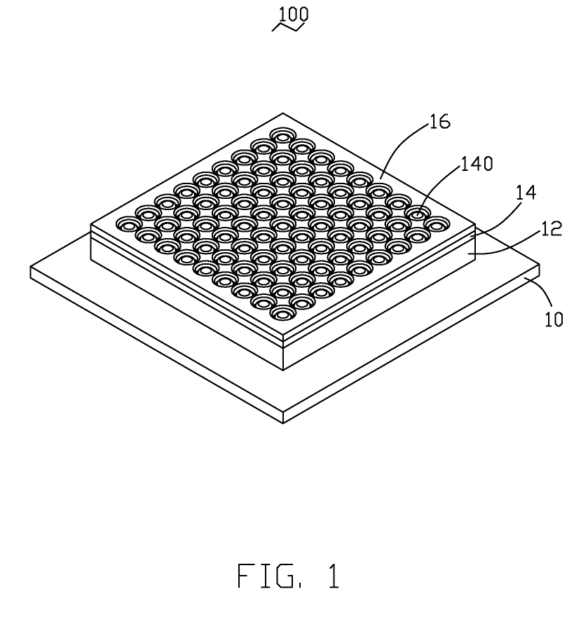

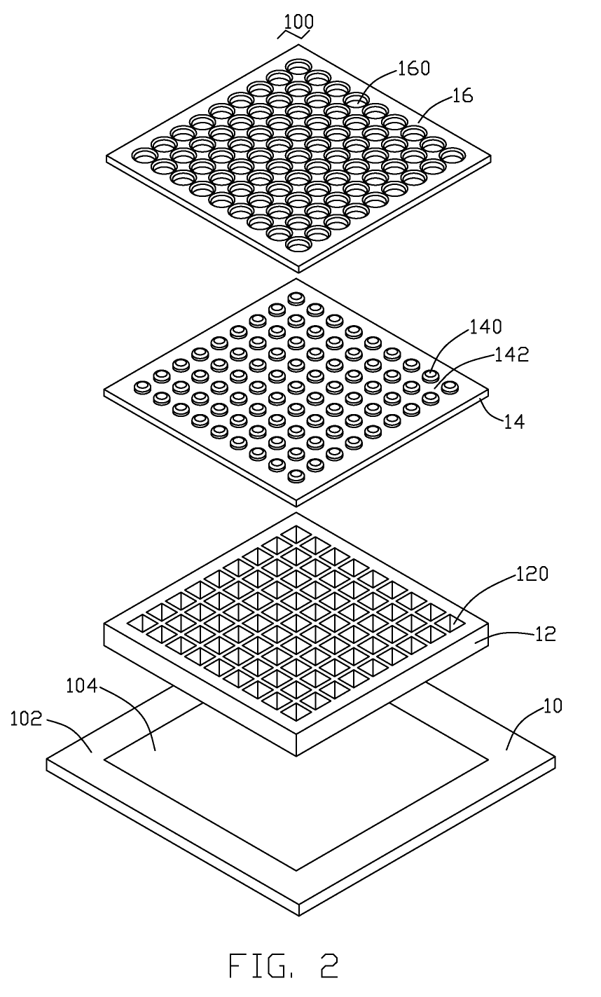

Referring to FIG. 1 and FIG. 2, a preferred embodiment of a camera module 100 includes, from bottom to top, an image sensor 10, a spacer 12, a lens module 14, and an aperture plate 16. The camera module 100 further includes a signal processor (not shown) electronically connected with the image sensor 10.

The image sensor 10 is at least one item selected from the group consisting of a complementary metal oxide semiconductor (CMOS) image sensor and a charge coupled device (CCD) image sensor. The image sensor 10 includes a base 102 and a sensor area/region 104 in the center of the base 102 (i.e., centered upon the base 102). To maximize the image sensing ability of the image sensor 10, it is advantageous for the sensor area 104 to occupy a major portion (e.g., ˜70% or more) of the total area available on the base 102.

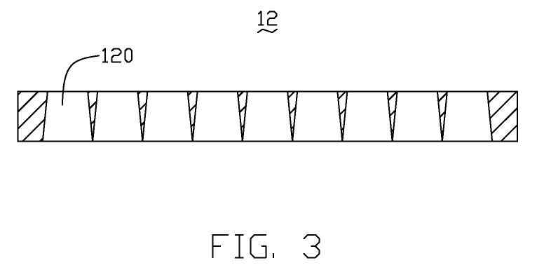

Referring also to FIG. 3, the spacer 12 has a similar shape to the sensor area 104. A plurality of light holes 120 is defined through the spacer 12. The image sensor 10 receives light through the light holes 120. Each of the plurality of light holes 120 is a bell-mouthed hole. That is, a cross-sectional plane of each of the plurality of light holes 120 is trapezoidal in shape, wherein the wider end of the trapezoid is located towards (i.e., proximate or adjacent) the image sensor 10. There is a near zero-distance between the corresponding larger ends of each pair of neighboring light holes 120, so that the negative optical effect caused by an interval between the neighboring light holes 120 can be avoided or at least greatly minimized.

The lens module 14 includes a plurality of lenses 140 and a tray 142 configured for carrying/containing the lenses 140. Each of the lenses 140 is a spherical or aspherical optical lens. A plurality of containing holes (not labeled) is defined through the tray 142. The plurality of containing holes is arranged in an array. The containing holes are used for containing/holding the respective lenses 140. The size of each containing hole corresponds to that of the lenses 140. When the lenses 140 are put in the tray 14, there is no negative effect on the optics of the lenses 140.

The aperture plate 16 has a plurality of through holes 160 defined therethrough. The distribution of the through holes 160 is essentially identical to that of the lenses 140 and, thus, corresponds to the layout of the containing holes in the tray 142. The lenses 140 can receive light through the through holes 160. Each of the through holes 160 is a bell-mouthed hole opening outwardly. The size of each of the through holes 160 corresponds to the size of the optical part of a lens 140. It should be understood that the through holes 160 can be omitted and be replaced with a transparent material. In either case, the through holes 160 or the transparent material serves as a light permeable portion. Through such light permeable portions, the lenses 140 are able to receive light.

The area of the spacer 12, the tray 142, and the aperture 16 is about the same. The light holes 120, the containing holes, and the through holes 160 are arranged in the same pattern/configuration. The area of the light hole 120 is larger than that of the light permeable portion, so that the camera module 100 can better receive light. The aperture plate 16, the lens module 14, and the spacer 12 are deposited on the sensor area 104 of the image sensor 10. Each of the light holes 120 is positioned corresponding to a respective lens 140, positioned in the corresponding containing hole, and to a respective through hole 160. The image sensor 10 receives the outer light 10 through the plurality of lenses 140 and processes the light to form image signals. The image signals are sent to a signal processor (not shown) by the image sensor 10. The signal processor consolidates the respective images from each of the lenses 140 to remove any alignment errors, so that a final image can be reconstructed. Of course, the signal processor can be replaced with a program used in the image sensor 10. The program can be used for image consolidation and correction.

It should be understood that each of the through holes 160 may be staggered a little with respect to each of the corresponding light holes 120, so that different view fields can be sufficiently covered. The spacer 12, tray 142, and the aperture plate 16 are, advantageously, made of plastic and connected together by epoxy resin or another suitable adhesive. The lenses 140 and the tray 142 can, alternatively, be formed as a single-piece unit, and, thus, the containing holes in the tray 142 can be omitted. The spacer 12 can be omitted. In an instance where the spacer 12 is omitted, the thickness of the tray 142 is larger than that of the lenses 140, so that the lens module 14 can be positioned directly on the sensor area 104 of the image sensor 10. With the lenses 140 distributed in an array in the manner of the present system, the camera module 100 is thinner than the traditional camera module.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A camera module, comprising:
an image sensor including a base and a sensor area located in the center of the base;
a lens module including a plurality of lenses and a container for holding the lenses, the lenses being distributed in an array within the container; and
an aperture plate including a plurality of light permeable portions located corresponding to respective lens positions;
wherein the lens module and the aperture plate respectively correspond to the sensor area, and the area of the container corresponds to the area of the aperture plate.

2. The camera module as claimed in claim 1, wherein the camera module further comprises a spacer provided between the image sensor and the lens module; the area of the spacer corresponds to the area of the container and the area of the aperture plate; a plurality of light holes are defined through the spacer; and the distribution of the light holes corresponds to the distribution of the lenses and the light permeable portions.

3. The camera module as claimed in claim 2, wherein the plurality of light permeable portions is comprised of at least one of a plurality of through holes defined through the spacer and a transparent material.

4. The camera module as claimed in claim 3, wherein each of the light permeable holes is a bell-mouthed-shaped hole, a cross-sectional plane of each such bell-mouthed-shaped hole being trapezoidal in shape, a larger end of the trapezoid being located towards the image sensor.

5. The camera module as claimed in claim 4, wherein a near zero-distance exists between the corresponding larger ends of each pair of neighboring light holes.

6. The camera module as claimed in claim 1, wherein the container is a tray with a plurality of containing holes defined therethrough, the size of each containing hole corresponding to a respective one of the lenses.

7. The camera module as claimed in claim 1, wherein the lenses and the container are formed in a single unit, and a thickness of the container is larger than a respective thickness of each of the lenses.

8. The camera module as claimed in claim 2, wherein the spacer, tray and the aperture plate are made of plastic and assembled together by epoxy resin.

9. The camera module as claimed in claim 1, wherein each of the lenses is a spherical or aspherical optical lens.
